(19) United States
(12) Patent Application Publication
(10) Pub. No.: US 2023/0123651 A1
(43) Pub. Date: Apr. 20, 2023

(54) IMAGE SENSING DEVICE

(71) Applicant: Egis Technology Inc., Hsinchu City (TW)

(72) Inventors: Yu-Hsuan Lin, Hsinchu City (TW); Tzu-Yang Peng, Hsinchu City (TW); Chung-Yi Wang, Hsinchu City (TW); Tzu-Li Hung, Hsinchu City (TW)

(73) Assignee: Egis Technology Inc., Hsinchu City (TW)

(21) Appl. No.: 17/908,528

(22) PCT Filed: Jan. 8, 2021
(86) PCT No.: PCT/CN2021/070762

§ 371 Date: Aug. 31, 2022

Related U.S. Application Data
(60) Provisional application No. 62/992,169, filed on Mar. 20, 2020.

(51) Int. Cl. H04N 25/57; H03F 3/45; H04N 25/78

(52) U.S. Cl. CPC H04N 25/57; H03F 3/45475; H04N 25/78

(57) ABSTRACT

“An image sensing device is provided in the present invention. A control circuit determines a voltage change rate of a sensing signal according to a voltage value of the sensing signal generated by a light sensing unit during an estimation period, and controls an input adjustment circuit during an exposure period according to the voltage change rate to provide an input adjustment signal to a negative input end of an operational amplifier, such that a signal value of an amplified signal falls within a pre-set range during the exposure period.”

### TECHNICAL FIELD

The present invention relates to a sensing device, and in particular relates to an image sensing device.

### RELATED ART

A common image sensing device may include a sensing pixel array composed of multiple sensing pixels. Each of the sensing pixels converts incident light into a sensing signal. An image sensed by the image sensing device is obtained by analyzing the sensing signal provided by each of the sensing pixels. Further, each of the sensing pixels may include a photodiode, which converts light into an electrical signal. The continuous exposure of the photodiode causes the voltage value of the sensing signal output by the sensing pixel to drop continuously. The image sensed by the image sensing device may be obtained by reading the voltage value of the sensing signal provided by each of the sensing pixels.

Generally speaking, in order to improve the sensitivity of the image sensing device, the size of the sensing pixel is increased as much as possible to increase the charge generated by the sensing pixel after being exposed to light, such that there is still a certain amount of charge under low illumination. Although this may effectively improve the sensitivity of the image sensing device, due to increasing the size of the sensing pixel, the parasitic capacitance on the sensing pixel is also increased, and the capacitive elements in the back-end circuit must also increase their capacitance correspondingly to prevent the signal output by the back-end circuit according to the sensing signal from exceeding the acceptable dynamic range. Although increasing the capacitance of the capacitive element in the back-end circuit may solve the issue that the output signal exceeds the acceptable dynamic range, when the sensing pixel is in a low illumination environment, it also causes the issue that the voltage value output by the back-end circuit is too small, which is not conducive to signal analysis.

### SUMMARY OF THE INVENTION

The present invention provides an image sensing device, which may effectively improve the image sensing quality.

The image sensing device of the present invention includes a light sensing unit, an amplifier circuit, an analog-to-digital converter, an input adjustment circuit, and a control circuit. The light sensing unit receives a light signal including image information to generate a sensing signal. The amplifier circuit is coupled to the light sensing unit, and amplifies the sensing signal to generate an amplified signal. The amplifier circuit includes a capacitor and an operational amplifier. A negative input end of the operational amplifier is coupled to the light sensing unit, a positive input end of the operational amplifier is coupled to a first reference voltage, and the capacitor is coupled between a negative input end and an output end of the operational amplifier. The analog-to-digital converter is coupled to the output end of the operational amplifier, and converts the sensing signal into a digital signal. The input adjustment circuit is coupled to the negative input end of the operational amplifier. The control circuit is coupled to the analog-to-digital converter and the input adjustment circuit. The control circuit determines a voltage change rate of the sensing signal according to a voltage value of the sensing signal during an estimation period, and controls the input adjustment circuit during an exposure period according to the voltage change rate to provide an input adjustment signal to the negative input end of the operational amplifier, such that a signal value of the amplified signal falls within a pre-set range during the exposure period.

Based on the above, the embodiment of the present invention determines a voltage change rate of the sensing signal according to the voltage value of the sensing signal generated by the light sensing unit during the estimation period, and controls the input adjustment circuit during an exposure period according to the voltage change rate to provide an input adjustment signal to the negative input end of the operational amplifier, such that the signal value of the amplified signal falls within a pre-set range during the exposure period. In this way, the signal value of the sensing signal may be prevented from being too large, such that the analog-to-digital converter may not correctly read the sensing signal due to insufficient dynamic range, therefore the image sensing quality may be effectively and greatly improved.

In order to make the above-mentioned features and advantages of the present invention comprehensible, embodiments accompanied with drawings are described in detail below.

### BRIEF DESCRIPTION OF THE DRAWING

FIG. 1 is a schematic diagram of an image sensing device according to an embodiment of the present invention.

FIG. 2 is a schematic diagram of an image sensing device according to another embodiment of the present invention.

FIG. 3 is a schematic diagram of waveforms of a selection control signal, a reset signal, and a sensing signal according to an embodiment of the present invention.

FIG. 4 is a schematic of an image sensing device according to another embodiment of the present invention.

FIG. 5 is a schematic diagram of an image sensing device according to another embodiment of the present invention.

FIG. 6 is a schematic diagram of an image sensing device according to another embodiment of the present invention.

FIG. 7 is a schematic diagram of waveforms of a selection control signal, a reset signal, and a sensing signal according to another embodiment of the present invention.

### DETAILED DESCRIPTION OF DISCLOSED EMBODIMENTS

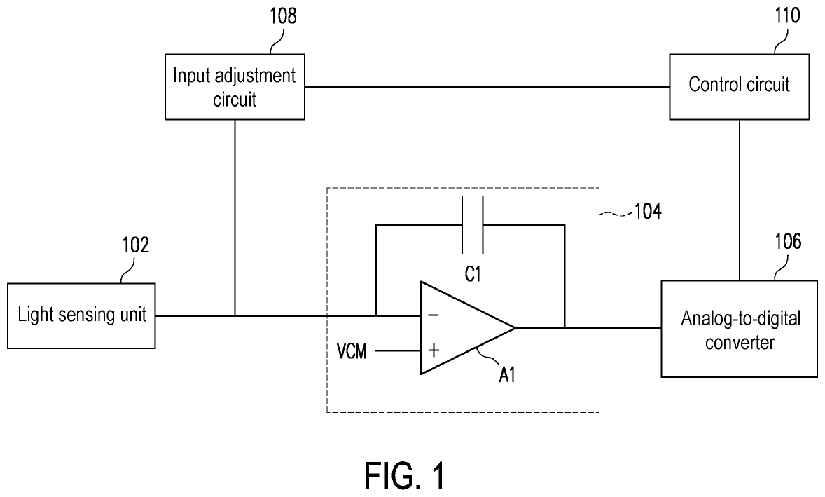

FIG. 1 is a schematic diagram of an image sensing device according to an embodiment of the present invention, please refer to FIG. 1. The image sensing device may include a light sensing unit 102, an amplifier circuit 104, an analog to digital converter (ADC) 106, an input adjustment circuit 108, and a control circuit 110. The amplifier circuit 104 is coupled to the light sensing unit 102, the analog-to-digital converter 106, and the input adjustment circuit 108. The control circuit 110 is coupled to the analog-to-digital converter 106 and the input adjustment circuit 108. In one embodiment, the image sensing device may be, for example, a fingerprint sensor or an X-ray flat panel sensor, but not limited thereto. Further, the amplifier circuit 104 includes an operational amplifier A1 and a capacitor C1. The negative input end of the operational amplifier A1 is coupled to the light sensing unit 102 and the input adjustment circuit 108, the positive input end of the operational amplifier A1 is coupled to a reference voltage VCM, and the output end of the operational amplifier A1 is coupled to the analog-to-digital converter 106. The capacitor C1 is coupled between the negative input end and the output end of the operational amplifier A1.

The light sensing unit 102 may receive a light signal including the image information to generate a sensing signal. As the exposure period of the light sensing unit 102 becomes longer, the voltage value of the sensing signal correspondingly decreases. The amplifier circuit 104 may amplify the sensing signal to generate an amplified signal to the analog-to-digital converter 106, and the analog-to-digital converter 106 may convert the amplified signal into a digital signal and output the digital signal to the control circuit 110 for image analysis and processing. In one embodiment, the control circuit 110 may be, for example, a digital signal processing circuit, but not limited thereto. In addition, the control circuit 110 may know about the changes of the signal value of the sensing signal, such as the voltage value of the sensing signal, during the exposure period of the light sensing unit 102 according to the digital signal. The exposure period of the light sensing unit 102 may include an estimation period, and the control circuit 110 may determine the voltage change rate of the sensing signal according to the voltage value of the sensing signal during the estimation period, and then estimate the degree of drop in the voltage value of the sensing signal at the end of the exposure period.

When the control circuit 110 determines that the voltage value of the sensing signal at the end of the exposure period will cause the signal value of the amplified signal provided by the amplifier circuit 104 to exceed the dynamic range of the analog-to-digital converter 106, the control circuit 110 may control the input adjustment circuit 108 to provide an input adjustment signal to the negative input end of the operational amplifier A1 during the exposure period of the sensing unit 102 according to the voltage change rate of the sensing signal to change the difference between the positive input end and the negative input end of operational amplifier A1. Thereby during the exposure period of the light sensing unit 102, the signal value of the amplified signal provided by the amplifier circuit 104 is adjusted to fall within a pre-set range without exceeding the dynamic range of the analog-to-digital converter 106, in which the pre-set range is less than or equal to the dynamic range of the analog-to-digital converter 106. In this way, the signal value of the sensing signal may be prevented from being too large, such that the analog-to-digital converter 106 may not correctly read the sensing signal due to insufficient dynamic range, therefore the image sensing quality may be effectively and greatly improved.

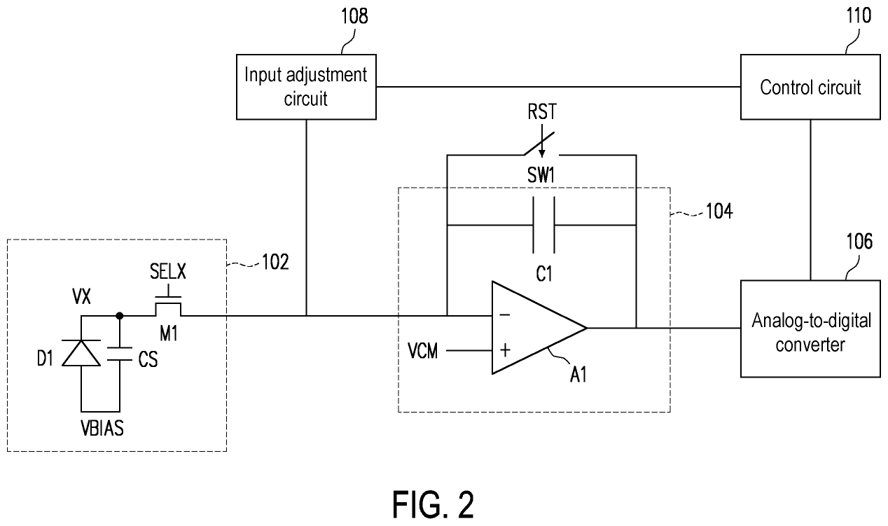

FIG. 2 is a schematic diagram of an image sensing device according to another embodiment of the present invention. In this embodiment, the light sensing unit 102 may include a selection switch M1, a photoelectric conversion unit D1, and a parasitic capacitance CS, in which one end of the selection switch M1 is coupled to the negative input end of the budget amplifier A1, the photoelectric conversion unit D1 is coupled between the other end of the selection switch M1 and a voltage VBIAS, and the parasitic capacitance CS is generated between a common contact of the photoelectric conversion unit D1 and the selection switch M1 and the voltage VBIAS. The voltage VBIAS may be, for example, a ground voltage, the photoelectric conversion unit D1 may be, for example, a photodiode, and the selection switch M1 may be implemented by, for example, a transistor, but not limited thereto. In addition, the image sensing device of this embodiment further includes a reset switch SW1, and the reset switch SW1 and the capacitor C1 are connected in parallel between the negative input end and the output end of the operational amplifier A1.

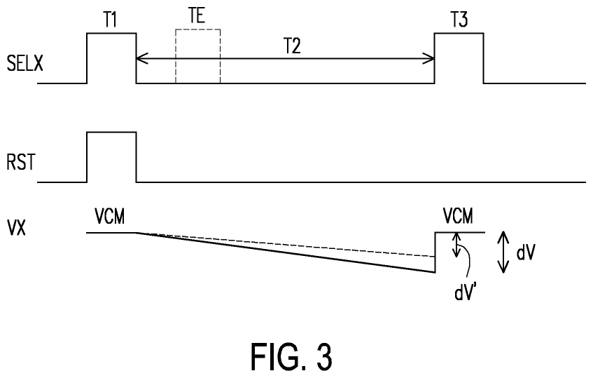

The photoelectric conversion unit D1 may convert the light signal into an electrical signal (sensing signal). As shown in FIG. 3, before the light sensing unit 102 is selected to output a sensing signal, the selection switch M1 and the reset switch SW1 are respectively controlled by a selection control signal SELX and a reset signal RST to enter a conducting state during a reset period T1. At this time, a voltage VX will be reset to the same voltage value as the reference voltage VCM. Then, in an exposure period T2, the selection switch M1 and the reset switch SW1 are respectively controlled by the selection control signal SELX and the reset signal RST to enter an off state. During the exposure period T2, the voltage VX on the photoelectric conversion unit D1 will gradually decrease as the exposure time of the photoelectric conversion unit D1 is prolonged. During the output period T3, the selection switch M1 is controlled by the selection control signal SELX to enter the conducting state. At this time, the output voltage of the operational amplifier A1 is equal to a voltage difference dV between the reference voltage VCM and the voltage VX multiplied by the gain value of the operational amplifier A1.

In order to prevent the output voltage of the operational amplifier A1 from exceeding the dynamic range of the analog-to-digital converter 106 at the back-end, in one embodiment, the selection switch M1 is first turned on by the control signal SELX during the estimation period, in which the estimation period TE may have the same time length as the output period T3, but not limited thereto. During the estimation period TE, the amplifier circuit 104 may perform analog-to-digital conversion for the analog-to-digital converter 106 according to the reference voltage VCM and the output voltage of the voltage VX, such that the control circuit 110 may know about the voltage change rate of the voltage VX during the estimation period TE. In this way, the control circuit 110 may estimate the degree of drop of the voltage VX at the end of the exposure period T2 (e.g., the voltage difference dV) according to the voltage change rate of the voltage VX during the estimation period TE.

If the control circuit 110 determines that the voltage difference dV will exceed the dynamic range of the analog-to-digital converter 106 after being amplified by the amplifier circuit 104, the control circuit 110 may control the input adjustment circuit 108 to provide an input adjustment signal to the negative input end of the operational amplifier A1 during the exposure period T2 according to the voltage change rate of the voltage VX during the estimation period TE, to adjust the voltage value of the voltage VX such that the voltage VX may meet the dynamic range requirement of the analog-to-digital converter 106 when the exposure period T2 ends. As shown in FIG. 3, through the adjustment of the input adjustment circuit 108, the degree of drop of the voltage VX at the end of the exposure period T2 is reduced from the voltage difference dV to a voltage difference dV′ (as shown by the dotted line), which may effectively prevent the output voltage of the operational amplifier A1 from exceeding the dynamic range of the analog-to-digital converter 106. It is worth noting that the estimation period TE is included in the exposure period T2, but the time length, the starting point, and the end point of the estimation period TE are not limited to the embodiment shown in FIG. 3, but may be designed according to actual situations.

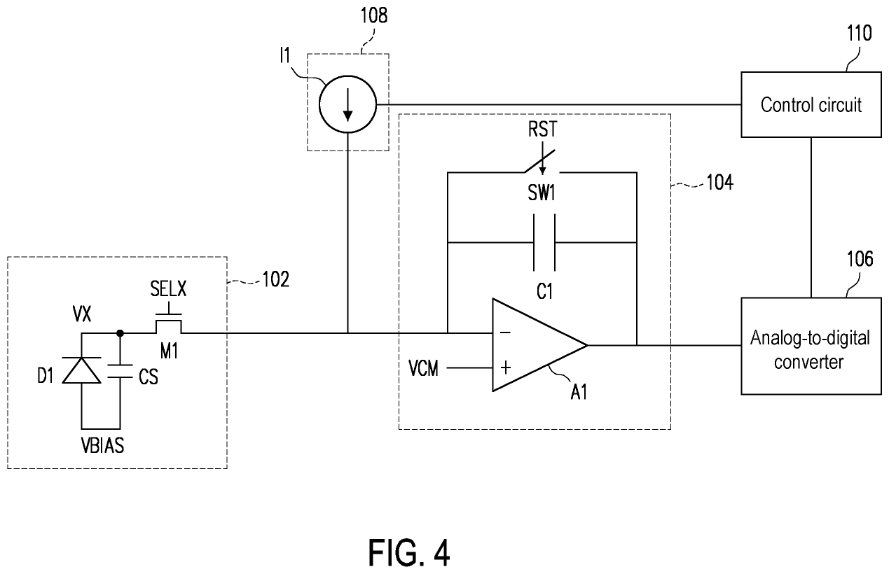

FIG. 4 is a schematic diagram of an image sensing device according to another embodiment of the present invention. In this embodiment, the input adjustment circuit 108 may be implemented by a current source I1, and the control circuit 110 may control the input adjustment circuit 108 to provide the input adjustment current I1 to the negative input end of the operational amplifier A1 during the exposure period T2 according to the voltage change rate of the voltage VX during the estimation period TE to adjust the voltage value of the voltage VX.

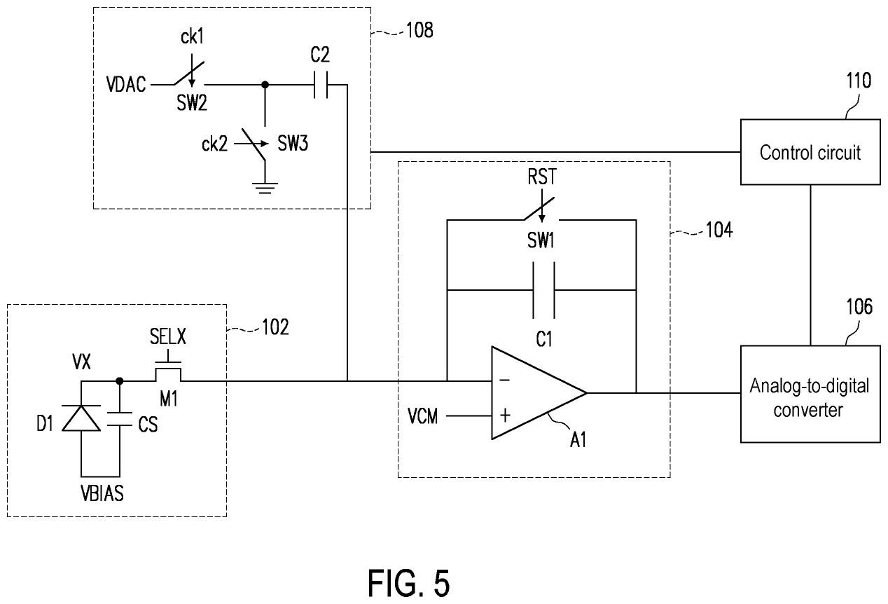

It should be noted that the input adjustment signal is not limited to the current signal. As shown in FIG. 5, in the embodiment of FIG. 5, the input adjustment circuit 108 may include switches SW2, SW3, and a capacitor C2, in which one end of the capacitor C2 is coupled to the negative input end of the operational amplifier A1, the switch SW2 is coupled between a reference voltage VDAC and the other end of the capacitor C2, and the switch SW3 is coupled between a common contact of the switch SW2 and the capacitor C2 and the ground. The control circuit 110 may output switching control signals ck1 and ck2 to turn on the switches SW2 and SW3 alternately during the exposure period T2 according to the voltage change rate of the voltage VX during the estimation period TE, that is, when the switch SW2 is in the conducting state, the switch SW3 will be in the off state, and when the switch SW2 is in the off state, the switch SW3 will be in the conducting state. By turning on the switches SW2 and SW3 alternately in this way, the input adjustment circuit 108 may generate an input adjustment voltage to the negative input end of the operational amplifier A1, thereby adjusting the voltage value of the voltage VX.

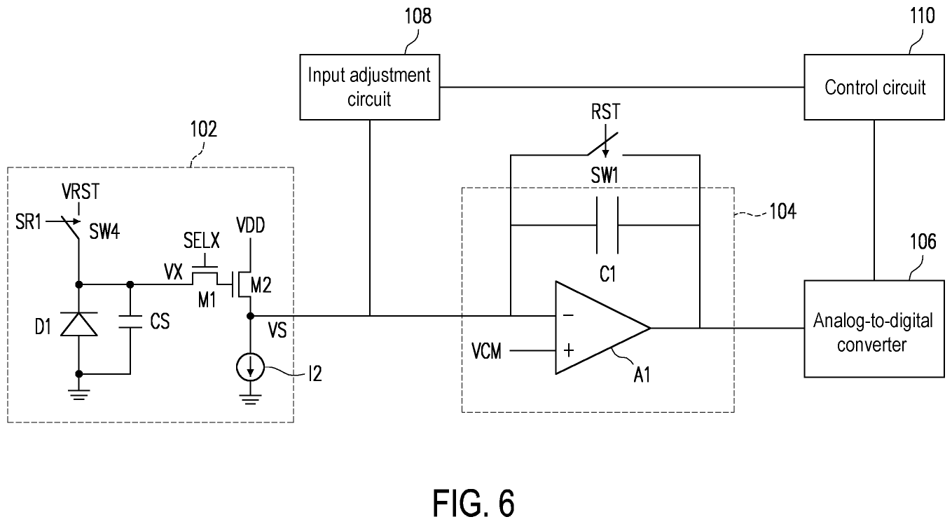

FIG. 6 is a schematic diagram of an image sensing device according to another embodiment of the present invention. In this embodiment, the light sensing unit 102 may include a reset switch SW4, a selection switch M1, a transistor M2, a photoelectric conversion unit D1, a parasitic capacitance CS, and a current source 12, in which one end of the reset switch SW4 is coupled to a reset voltage VRST, the photoelectric conversion unit D1 is coupled between the reset switch SW4 and the ground, and the parasitic capacitance CS is generated between a common contact of the photoelectric conversion unit D1 and the reset switch SW4 and the ground. The selection switch M1 is coupled between a common contact of the photoelectric conversion unit D1 and the reset switch SW4 and the gate of the transistor M2, one end of the transistor M2 is coupled to a power supply voltage VDD, and the current source 12 is coupled between the other end of the transistor M2 and the ground.

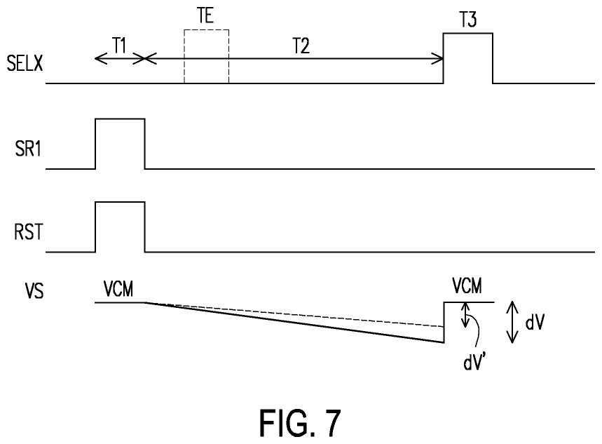

As shown in FIG. 7, during the reset period T1, the reset switch SW4 is controlled by the reset signal SR1 to be in a conducting state, and the selection switch M1 is controlled by the selection control signal SELX to be in an off state. At this time, the voltage VX will be reset to the same voltage value as the reset voltage VRST. During the exposure period T2, the reset switch SW1 is controlled by the reset signal RST to enter an off state. During the exposure period T2, the voltage VX on the photoelectric conversion unit D1 will decrease as the exposure time of the photoelectric conversion unit D1 is prolonged. During the output period T3, the selection switch M1 is controlled by the selection control signal SELX to enter the conducting state, and the source follower composed of the transistor M2 and the current source 12 may output a voltage VS to the negative input end of the operational amplifier A1 according to the voltage VX. The output voltage of the operational amplifier A1 is equal to the voltage difference dV between the reference voltage VCM and the voltage VS multiplied by the gain value of the operational amplifier A1.

Similar to the embodiment of FIG. 2, in order to prevent the output voltage of the operational amplifier A1 from exceeding the dynamic range of the analog-to-digital converter 106 at the back-end, the selection switch M1 may be first put into the conducting state by the control signal SELX during the estimation period TE. During the measurement period TE, the amplifier circuit 104 may perform analog-to-digital conversion for the analog-to-digital converter 106 according to the reference voltage VCM and the output voltage of the voltage VS, such that the control circuit 110 may know about the voltage change rate of the voltage VS during the estimation period TE. In this way, the control circuit 110 may estimate the degree of drop in the voltage VS at the end of the exposure period T2 (e.g., the voltage difference dV) according to the voltage change rate of the voltage VS during the estimation period TE.

If the control circuit 110 determines that the voltage difference dV will exceed the dynamic range of the analog-to-digital converter 106 after being amplified by the amplifier circuit 104, the control circuit 110 may control the input adjustment circuit 108 to provide an input adjustment signal to the negative input end of the operational amplifier A1 during the exposure period T2 according to the voltage change rate of the voltage VS during the estimation period TE, to adjust the voltage value of the voltage VS such that the voltage VS may meet the dynamic range requirement of the analog-to-digital converter 106 when the exposure period T2 ends. As shown in FIG. 7, through the adjustment of the input adjustment circuit 108, the degree of drop of the voltage VS at the end of the exposure period T2 is reduced from the voltage difference dV to a voltage difference dV′ (as shown by the dotted line), which may effectively prevent the output voltage of the operational amplifier A1 from exceeding the dynamic range of the analog-to-digital converter 106.

To sum up, the embodiment of the present invention determines a voltage change rate of the sensing signal according to the voltage value of the sensing signal generated by the light sensing unit during the estimation period, and controls the input adjustment circuit during an exposure period according to the voltage change rate to provide an input adjustment signal to the negative input end of the operational amplifier, such that the signal value of the amplified signal falls within a pre-set range during the exposure period. In this way, the signal value of the sensing signal may be prevented from being too large, such that the analog-to-digital converter may not correctly read the sensing signal due to insufficient dynamic range, therefore the image sensing quality may be effectively and greatly improved.

Although the present invention has been described in detail with reference to the above embodiments, they are not intended to limit the present invention. Those skilled in the art should understand that it is possible to make changes and modifications without departing from the spirit and scope of the present invention. Therefore, the protection scope of the present invention shall be defined by the following claims.

What is claimed is:

1. An image sensing device, comprising:
a light sensing unit, receiving a light signal comprising image information to generate a sensing signal;
an amplifier circuit, coupled to the light sensing unit, amplifying the sensing signal to generate an amplified signal, comprising:
a capacitor; and
an operational amplifier, wherein a negative input end of the operational amplifier is coupled to the light sensing unit, a positive input end of the operational amplifier is coupled to a first reference voltage, and the capacitor is coupled between a negative input end and an output end of the operational amplifier;
an analog-to-digital converter, coupled to the output end of the operational amplifier, converting the sensing signal into a digital signal;
an input adjustment circuit, coupled to the negative input end of the operational amplifier; and
a control circuit, coupled to the analog-to-digital converter and the input adjustment circuit, determining a voltage change rate of the sensing signal according to a voltage value of the sensing signal during an estimation period, controlling the input adjustment circuit during an exposure period according to the voltage change rate to provide an input adjustment signal to the negative input end of the operational amplifier, such that a signal value of the amplified signal falls within a pre-set range during the exposure period.

2. The image sensing device according to claim 1, wherein the light sensing unit comprises:
a selection switch, wherein one end of the selection switch is coupled to the negative input end of the operational amplifier;
a photoelectric conversion unit, coupled between another end of the selection switch and a ground, converting the light signal into an electrical signal to generate the sensing signal; and
a parasitic capacitance, generated between a common contact of the photoelectric conversion unit and the selection switch and the ground, the light sensing unit generating the sensing signal on the common contact.

3. The image sensing device according to claim 2, further comprising:
a reset switch, wherein the reset switch and the capacitor are connected in parallel between the negative input end and the output end of the operational amplifier, during a reset period, the selection switch and the reset switch are in a conducting state, during the exposure period, the selection switch and the reset switch are in an off state, and during the estimation period and an output period, the selection switch is in the conducting state and the reset switch is in the off state.

4. The image sensing device according to claim 3, wherein the estimation period and the output period have a time length that is the same.

5. The image sensing device according to claim 1, wherein the input adjustment circuit comprises:
a current source, coupled to the control circuit and the negative input end of the operational amplifier, the control circuit controls the current source during the exposure period according to the voltage change rate of the sensing signal to provide an input adjustment current to the negative input end of the operational amplifier.

6. The image sensing device according to claim 1,
a capacitor, wherein one end of the capacitor is coupled to the negative input end of the operational amplifier;
a first switch, coupled between another end of the capacitor and a second reference voltage; and
a second switch, coupled between the another end of the capacitor and a ground, the control circuit controlling the first switch and the second switch to alternately turn on during the exposure period according to the voltage change rate of the sensing signal to provide an input adjustment voltage to the negative input end of the operational amplifier.

7. The image sensing device according to claim 1,
a reset switch, wherein a first end of the reset switch is coupled to a reset voltage;
a selection switch, wherein a first end of the selection switch is coupled to a second switch of the reset switch;
a photoelectric conversion unit, coupled between the first end of the selection switch and a ground, converting the light signal to an electrical signal to generate the sensing signal;
a parasitic capacitance, generated between a common contact of the photoelectric conversion unit and the selection switch and the ground, the light sensing unit generating the sensing signal on the common contact of the photoelectric conversion unit and the selection switch.
a transistor, wherein a first end of the transistor is couple to a power supply voltage, a second end of the transistor is coupled to the negative input end of the operational amplifier, and a control end of the transistor is coupled to a second end of the selection switch; and
a current source, coupled between the second end of the transistor and the ground, wherein during a reset period, the reset switch is in a conducting state and the selection switch is in an off state, during the exposure period, the selection switch and the reset switch are in the off state, and during the estimation period and an output period, the selection switch is in the conducting state and the reset switch is in the off state.

8. The image sensing device according to claim 7, wherein the estimation period and the output period have a time length that is the same.

9. The image sensing device according to claim 1, wherein the exposure period comprises the estimation period.

10. The image sensing device according to claim 1, wherein the pre-set range is less than or equal to a dynamic range of the analog-to-digital converter.
